(19) United States
(12) Patent Application Publication
(10) Pub. No.: US 2006/0267653 A1
(43) Pub. Date: Nov. 30, 2006

(54) Single-event-effect hardened circuitry

(75) Inventor: David Fulkerson, Chanhassen, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/136,920

(22) Filed: May 25, 2005

(51) Int. Cl. H03K 3/356

(52) U.S. Cl. 327/208

(57) ABSTRACT

An apparatus and method for hardening a circuit against a single-event effect condition is provided. A first logic circuit outputs an output-signal event having a glitch impressed thereon. A glitch filter (i) receives the output-signal event, (ii) slows down a rate of change of the output-signal event by a given amount of time to produce a slowed output-signal event, and (iii) provides to a second logic circuit the slowed output-signal event. When a duration of the output-signal event is less than the given amount of time, the glitch filter prevents the slowed output-signal event from attaining an undesired-state threshold, which in turn prevents the second logic circuit from operating in an undesired state. An optional feedback module feeds a feedback-signal event without a glitch to the glitch filter. When the slowed output-signal event does not satisfy the undesired-state threshold, the feedback-signal event neutralizes the glitch impressed upon the output-signal event.

### GOVERNMENT STATEMENT

The United States Government may have acquired certain rights in this invention pursuant to Contract No. DTRA01-02-D-008 awarded by Defense Threat Reduction Agency.

### BACKGROUND

1. Field

The following relates to microelectronic circuits, and more particularly, to single-event effect (“SEE”) resistant or hardened circuits.

2. Related Art

Integrated circuits used in devices that operate in outer space, earth orbital space, and high atmospheric altitudes (e.g., commercial flight altitudes) generally have to be highly reliable and operate using very low levels of power. Along with these necessities, space, weight and cost limitations generally cause these integrated circuits to be very densely populated and highly complex.

As a consequence of operating in outer space, earth orbital space, and high atmospheric altitudes, however, the integrated circuits are exposed to a large amount of radiation, which can effect their operation and, in turn, their reliability. Because the Earth's magnetic field deflects most outer space radiation, terrestrial-based integrated circuits are not normally exposed to large amounts of radiation. Recently, however, several radiation-laden atmospheric storms, which emanated from a coronal mass ejection of the sun, expanded into space, penetrated the Earth's magnetic field and disrupted a significant amount of terrestrial-based devices that use integrated circuits.

The disruptions caused by the radiation events are believed to result from radiation particles interacting with the semiconductor materials (e.g., silicon) that make up the integrated circuits. These radiation particles are by-products of the natural decay of elements, and/or radiation protons, neutrons, electrons, and all the natural elements. The radiation particles are abundant in a wide range of energies in outer space, earth orbital space, high atmospheric altitudes (e.g., commercial flight altitudes), and, as noted above, terrestrial space.

When a radiation particle interferes with an integrated circuit, it can slow the circuit's performance and can even upset circuit operation. In Very Large Scale Integration (VLSI) circuits, radiation particles can also generate significant transient voltage and current disturbances on internal (e.g., power and ground) nodes.

A radiation particle striking and passing through the structure of a transistor (or any semiconductor device) creates hole-electron pairs along its path or “track.” These charges will migrate towards a high-voltage-state node of the transistor, resulting in a discharging current on the high-voltage node. If the discharging current exceeds, for example, the current holding a high-voltage state on the node, then the high-voltage-state node will transition to an undesired low state. The result of the flip-flopping of the states of the nodes is that an output of the transistor, and in turn, a larger system into which the transistor is integrated (e.g., a logic gate) may undesirably change.

The number of hole-electron pairs separated along the track length of the radiation particle, however, is finite, so the nodal voltage disturbances may be temporary or have only a transient effect. In addition, the density of the radiation particles striking the integrated circuit is generally small enough that the disturbances caused by the radiation particles are treated as single events in time. Such transient disturbances are known as “single-event transient” (SET) conditions.

After experiencing a SET condition, transistor nodes can return to their desired voltage states. Consequently, the SET condition might not be a problem in and of itself. The consequence of having a temporary voltage disturbance on the transistor node, however, may be problematic because the SET condition may be propagated through the larger system. For example, if one of the transistor nodes affected by a radiation particle is in a clock network, then the SET condition can generate a false clock pulse in the clock network portion of the system, thereby throwing off the timing of the larger system.

By way of anther example, if one of the transistor nodes affected by a radiation particle is in a data storage element, then the SET condition can flip a storage bit of the data storage element to an opposite state. Consequently, the contents of the data storage element are undesirably changed.

One such undesirable change may be illustrated by way of FIGS. 1a-1b. Each of these figures are timing charts that illustrate an exemplary clocking signal (CLK) and other exemplary signals present on various nodes, namely nodes D, E and Q, of a latch circuit 10 shown in FIG. 1c. As can be readily discerned, the latch circuit 10 includes a tri-state inverter 12, a feedback-controlled inverter 14, and a feedback tri-state inverter 16. Coupled to an input of the tri-state inverter 12 is input node D. Coupled in series to an output of the tri-state inverter 12 at node E is the feedback-controlled inverter 14 and feedback tri-state inverter 16. The feedback-controlled inverter 14 and feedback tri-state inverter 16, in turn, are coupled together at node Q.

In FIG. 1a, the timing chart illustrates an operation of the latch circuit 10 operating under normal operating conditions. That is, the timing chart of FIG. 1a is illustrative of the operation of the latch circuit 10 that does not experience change that results from a radiation particle strike. In FIG. 1b, on the other hand, the timing chart illustrates the undesirable operation of the latch circuit 10 when a radiation-particle strike causes a disturbance or “glitch” on a signal inputted into the latch circuit 10.

As set forth in each of the FIGS. 1a-1b, Curve 18 illustrates the CLK that may be fed along with the complement of the CLK, namely CLKN (not shown), to enable the tri-state inverter 12 and feedback tri-state inverter 16. Curve 20 illustrates the input signal that may be fed from input node D into the tri-state inverter 12. Curve 22 illustrates a nodal signal that is a resultant combination of output signals of the tri-state inverter 12 and the feedback-controlled inverter 14. Curve 24 illustrates an output signal fed from the feedback-controlled inverter 14 to node Q. In addition, at time to in each of the FIGS. 1a-1b, the CLK transitions to a HIGH state and an input signal received on node D is in a HIGH state.

Refer now to FIG. 1a at Curve 22. The output signal from the tri-state inverter 12, which results from the inversion of the input signal, transitions from its previous state to a LOW state as shown at time t1. Sometime thereafter at time t2, the output signal of the feedback-controlled inverter 14 transitions from its previous state to a HIGH state and is fed to the node Q, as shown in Curve 24. At time t3 (Curve 18), the CLK transitions to a LOW state and latches in the output signal on node Q, as shown in Curve 24. Because the input signal did not change as a result of a radiation particle strike, the output signal on node Q operates properly.

Now refer to FIG. 1b. The output signals of the tri-state inverter 12 and feedback-controlled inverter 14 transition as described above and as shown at times to and t1 in Curves 22, 24, respectively. Unlike FIG. 1, the input signal at time t4 undesirably transitions from its HIGH state to a LOW state as a result of a radiation particle strike to a transistor located somewhere upstream from the input node D. In turn, the output signal of the tri-state inverter 12 that is fed to node E transitions from its desired LOW state to an undesired HIGH state, as shown in Curve 22 at time t5. Consequently, the output signal of the feedback-controlled inverter 14 that is fed to node Q transitions from its proper HIGH state to an improper LOW state, as shown in Curve 24 at time t6.

At time t3 (Curve 18), the CLK transitions to a LOW state, and latches in the output signal on node Q in the improper LOW state, as shown in Curve 24. Because the input signal undesirably changed as a result of a radiation particle strike upstream, the undesired effect of the radiation particle strike or glitch is further propagated to node Q. If node Q is attached to a larger system, the glitch would be propagated to that larger system.

However, when one of the transistor nodes is in a logic device that feeds data to an input of a latch (or flip-flop, register, etc.), there may or may not be a consequence from the SET condition. For example, if the data recovers to a valid state from a SET condition before the latch closes (e.g., before time t3 in the above example), it may be of no consequence. If, on the other hand, the data does not recover to the valid state before the latch closes, then the wrong data state may be loaded into the latch, as described above. In any the above examples and/or other cases where the SET condition propagates through a larger system and causes an undesirable change in the state of the larger system, it may be referred to as a single-event upset (SEU) condition.

More generally, logic errors caused by SET and/or SEU conditions are known as “single-event effects” (SEE). The susceptibility of modem integrated circuits to single-event effects is heightened by the reduced feature size and higher clock speeds that are otherwise very desirable.

Some solutions attempting to mitigate SEU susceptibility require the use of relatively complex combinational logic circuitry to provide logical or temporal isolation of SEE that would otherwise cause errors. For example, a temporal sampling latch as illustrated in FIG. 2 and described in the article authored by D. G. Mavis and P. H. Eaton entitled “Soft Error Rate Mitigation Techniques for Modem Microcircuits” provides an elaborate and complicated circuit to mitigate the effects of a SEE. Details of the article may be found at in the Proc. of 2002 Intl. Phys. Symp., pp. 216-225, Apr. 2002. Proc. of 2002 Intl. Phys. Symp., pp. 216-225, Apr. 2002. See also U.S. Pat. No. 6,127,864 entitled “Temporally Redundant Latch for Preventing Single Event Disruptions in Sequential Integrated Circuits,” which also is an elaborate and complicated circuit to mitigate the effects of a SEE.

Besides being complicated, these solutions typically are not area efficient nor do they rid the larger system of the SEE. Rather, these solutions seek to only delay the SEE conditions. Further, logic and temporal isolation circuit solutions can affect overall circuit speed and may, in some cases, be applicable only to storage circuits. Thus, an area-efficient solution that provides an SEE-condition hardness and that is also applicable to various circuit types (such as combinational logic circuits as well as memory circuits) is needed.

### SUMMARY

An apparatus and method for hardening a circuit against a single-event effect condition is disclosed. The apparatus may include a first logic circuit for providing a plurality of output-signal events to a second logic circuit. When receiving a glitch on its input, the first logic circuit may provide to the second logic circuit a first output-signal event having the glitch impressed upon it. The apparatus may further include a glitch filter for slowing a rate of change of the first output-signal event by a given amount of time. When a duration of the first output-signal event is less than the given amount of time, then the glitch filter prevents the first output-signal event from attaining an undesired-state threshold, thereby preventing the second logic circuit from operating in the undesired state.

### BRIEF DESCRIPTION OF THE DRAWINGS

Preferred embodiments are described with reference to the following drawings, wherein like reference numerals refer to like elements in the various figures, and wherein:

FIGS. 1a-1b are timing charts illustrating exemplary signals of a prior art latch circuit shown in FIG. 1c;

FIG. 1c is a prior art block diagram of a latch circuit;

FIG. 2 is a prior art block diagram of a temporal sampling latch disclosed in an article entitled “Soft Error Rate Mitigation Techniques for Modem Microcircuits;”

FIG. 3 is a block diagram illustrating a glitch-filtering apparatus for hardening a logic circuit against short duration single-event effect conditions;

FIG. 4 is a second block diagram illustrating a glitch filter for hardening a logic circuit against short duration single-event effect conditions;

FIG. 5a is a third block diagram illustrating the glitch filter embodied as a capacitor;

FIGS. 5b-5c are timing charts each of which illustrates exemplary signals of a logic circuit employing the glitch-filter embodiment of FIG. 5a;

FIG. 6 is a circuit diagram of a modified NMOS transistor formed into an alternative embodiment of the glitch filter; and

FIG. 7 is a fourth block diagram illustrating a logic circuit employing an alternative embodiment of the glitch filter.

### DETAILED DESCRIPTION

Overview

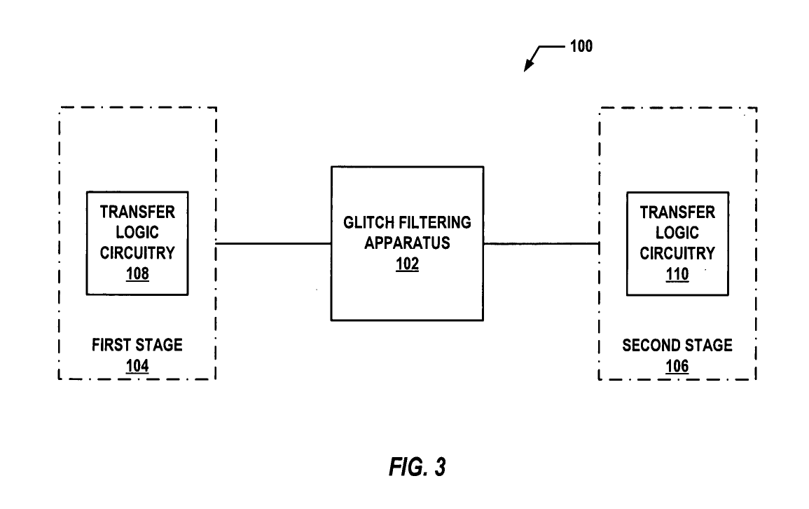

FIG. 3 is a block diagram illustrating a circuit 100 that includes a glitch-filtering apparatus 102 for hardening the circuit 100 against short duration Single-Event Effect (SEE) conditions. The glitch-filtering apparatus 102 (or multiples thereof) may be placed between first and second stages 104, 106 of a larger integrated or integral system. The first and second stages 104, 106 may, for example, be deployed with respective transfer logic circuitry 108, 110.

Each of the transfer logic circuitries 108, 110 may include, for example, a clocked tri-state inverter. However, it is recognized that each of the transfer logic circuitries 108, 110 may employ (or be used to drive) circuitry, such as a simple inverter, feed-forward or feedback inverters, latch circuitry and/or flip-flop circuitry. Further, the combination of transfer logic circuitries 108, 110 and the glitch-filtering apparatus 102 may be used with or used to modify any type of data storage element, including a memory cell, latch, register, etc.

To prevent a signal event resulting from a short duration single-event transient (SET) condition (i.e., a glitch) from propagating to the second stage from the first stage, the glitch-filtering apparatus 102 (hereinafter “glitch filter”) slows down a rate of change of the glitch. The glitch filter 102 does not time delay or shift the glitch and allow it to pass to second stage 106 and/or any stage thereafter. Instead, by slowing down the rate of change of the glitch, the glitch filter 102 allows the glitch to be swept from the circuit 100 altogether by a later application of a desired signal that is unaffected by the glitch. Consequently, the glitch filter 102 prevents the glitch from producing an SEU condition and/or allowing the glitch to be further propagated.

The glitch filter 102, however, is only effective against conditions in which the later application of the desired signal occurs before a switching point of the transfer logic circuitry 110. The switching point of the transfer logic circuitry 110 may depend upon signal threshold and response time of its transistors. Thus, the glitch filter 102 may be configured to slow the rate of change of the glitch by differing amounts based on the signal threshold, and response time of the transfer logic circuitry 110. By adjusting its charge storage rate (i.e., the rate at which the glitch filter may store charge), for example, the amount that the glitch filter 102 slows down the rate of change of the glitch can be varied.

Exemplary Glitch Filter

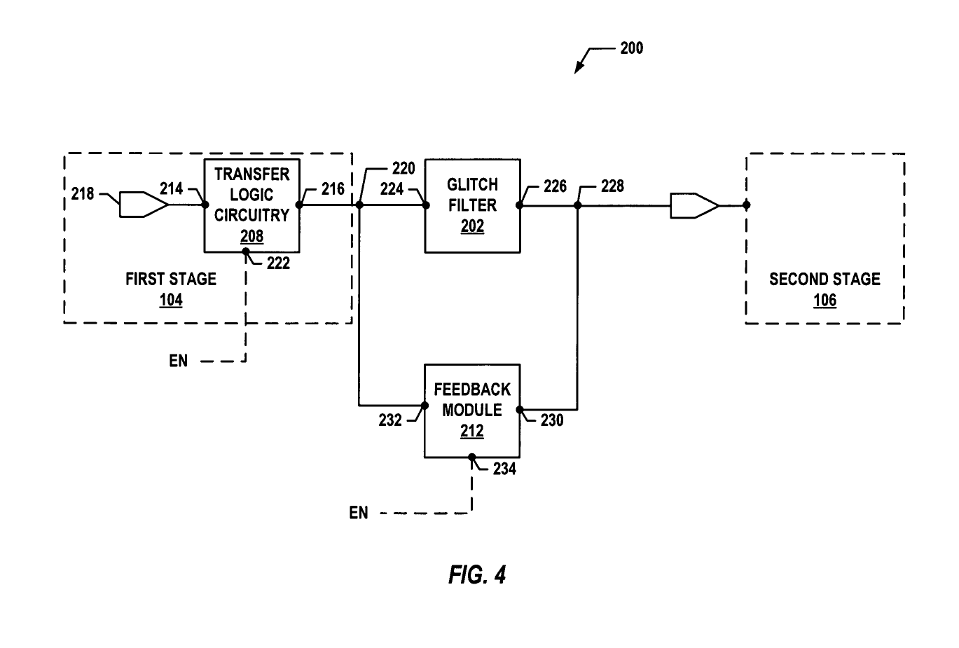

FIG. 4 is a block diagram illustrating a circuit 200 that employs a glitch filter. As noted above, the glitch filter conveniently provides hardening against short term SEE conditions, i.e., against SET and/or SEU conditions. In the configuration shown, transfer logic circuitry 208 of the first stage 104 is coupled in series with a feedback-controlled glitch filter 202. The feedback control may be provided by a feedback module 212.

The transfer logic circuitry 208 may be any type of logic circuitry, such as an inverter, AND gate, NAND gate, OR gate, NOR gate, etc. As such, transfer logic circuitry 208 may have one or more input and output terminals, such as input terminal 214 and output terminal 216. The input terminal 214 is operable to receive an input signal from node 218, and the output terminal 216 is operable to output to node 220 an output signal (“TL-output signal”) as a logic function of the input signal. The TL-output signal may be latched in a given state by a clocking signal or other timing signal received on an enable node 222.

When the clocking signal is in, for example, a HIGH state, the TL-output signal may be latched at its current state. This TL-output signal, whether latched or not, is fed to the node 220 and on to an input terminal 224 of the glitch filter 202. The glitch filter 202 applies a time rate of change function to the TL-output signal so as to produce a glitch-filtered output signal. The glitch filter 202 then feeds the glitch-filtered-output signal from its output terminal 226 to node 228. From node 228, glitch-filter-output signal is fed to the second stage 106 and to an input terminal 230 of the feedback module 212.

The feedback module 212 feeds a feedback signal to node 216 via its output terminal 232. Under desired operation, the feedback signal is in the same state of the desired TL-output signal of the transfer-logic circuitry 208, thereby maintaining the node 220 (that is coupled to the input of the second stage 106) in a desired state.

Like the transfer-logic circuitry, the feedback module 212 may be any type of logic circuitry, such as an inverter, AND gate, NAND gate, OR gate, NOR gate, etc. The feedback module 212 may be configured to provide the feedback in the same state of the desired TL-output signal when not affected by a particle induced glitch. The feedback signal may be optionally latched in a given state by a clocking signal or other timing signal received on an enable node 234. Depending on the type of logic circuitry of the feedback module 212, this clocking signal may be the same as and/or complement of the clocking signal supplied to the enable node 222 of the transfer-logic circuitry 208.

The construction (e.g., transistor-level fabrication and configuration) of transfer logic circuitry 208 and the feedback module 212 may themselves provide a certain level of hardness against single-event effect conditions. For instance, instead of using non-radiation hardened inverters, the transfer logic circuitry 208 may employ stacked-transistor tri-state inverters or other logic devices configured to limit susceptibility to energetic particles. In a stacked-transistor tri-state inverter configuration, each sensitive N-Channel and P-Channel Metal-Oxide-Semiconductor (MOS) transistors may be replaced with a stacked pair of respective N-Channel or P-Channel MOS transistors. Such a configuration allows an electrical signal that results from a radiation particle striking one (and possibly two) of the MOS transistors from being propagated to an output of the stacked-transistor tri-state inverter.

Details of exemplary stacked-transistor tri-state inverters and other logic devices that are constructed to limit susceptibility energetic particles may be found in U.S. patent application Ser. No. 10/759,913, filed Jan. 15, 2004 and entitled: “Radiation Hardening of Logic Circuitry Using a Cross-enabled, Interlocked Logic System and Method,”; and U.S. patent application Ser. No. 11/002,163, filed Dec. 2, 2004 and entitled “Single Event Upset Hardened Circuitry without Sensitivity to Overshoot and/or Undershoot Conditions,” both of which are commonly owned by the assignee of the present application and fully incorporated herein by reference.

The glitch filter 202 may include passive and/or active electronic components that can change and/or slow down the rate of change of the TL-output signal. The glitch filter 202 may be, for example, a capacitor, integrator and/or other device that combines its input with a time variable to provide an output that has a slowed rate of change from its input.

Exemplary Alternative Architecture

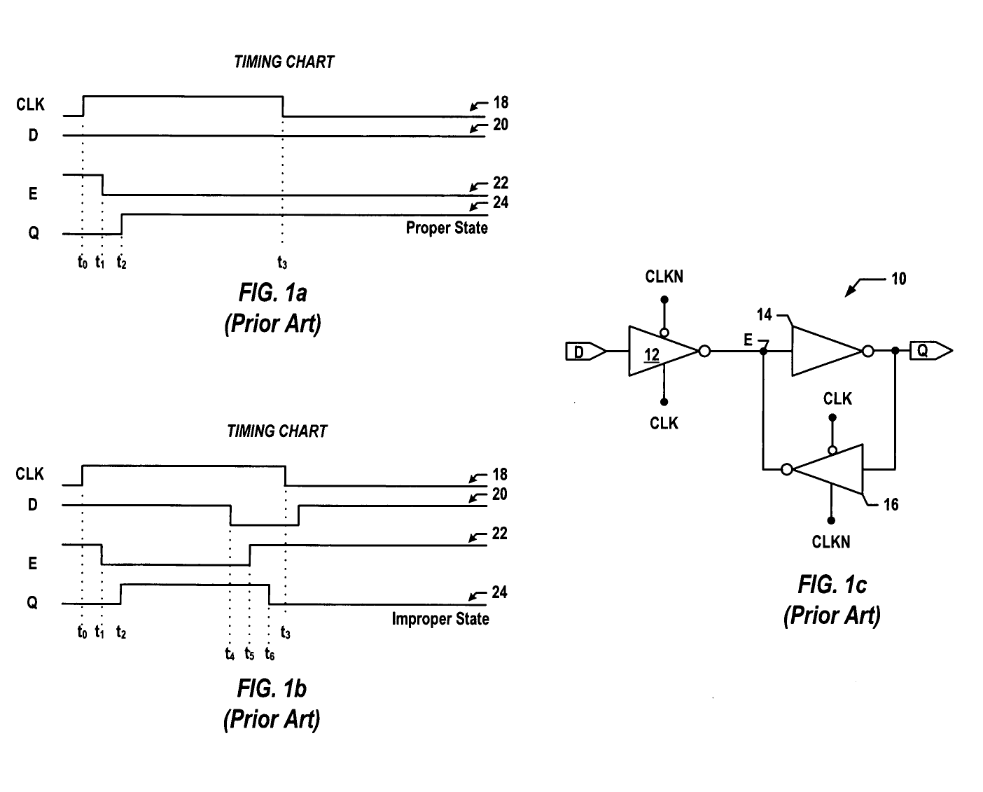

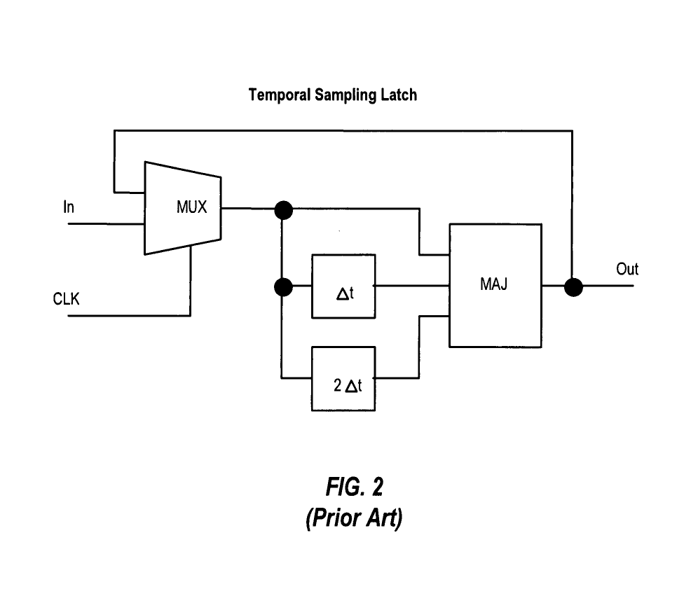

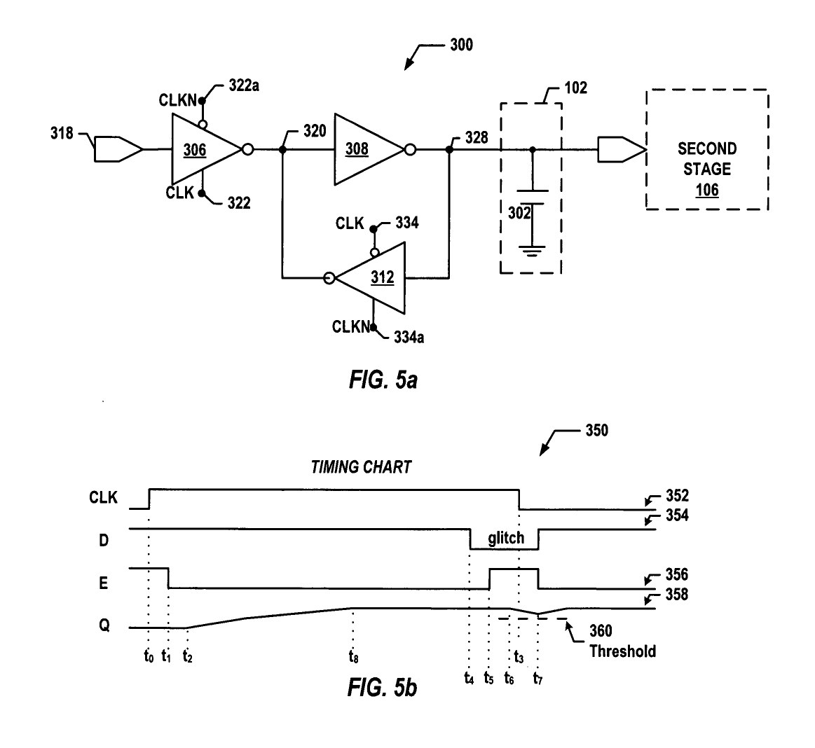

FIG. 5a is a block diagram illustrating a circuit 300 employing a glitch filter, such as the glitch filter 102 (FIG. 1). In this configuration, the circuit 300 includes a feedforward tri-state inverter 306 coupled in series at node 320 with a feedback-controlled feedforward inverter 308. The feedback control may be provided by a feedback tri-state inverter 312. The feedback-controlled feedforward inverter 308 in turn is coupled at node 328 to the glitch filter 102, which includes a capacitor 302. The second stage 106 may also be coupled to node 328.

Like circuit 200, the construction of the feedforward tri-state inverter 306, feedforward inverter 308, and/or feedback tri-state inverter 312 may be formed from non-hardened or, alternatively, hardened circuitry. When formed from hardened circuitry, these devices provide a level of hardness against SEE conditions and may be configured to limit susceptibility to radiation particles. Given that the redundancy of transistors in the hardened circuitry may slow the response time of the circuit as a whole, and may require more circuit-fabrication area, the feedforward tri-state inverter 306, feedforward inverter 308, and/or feedback tri-state inverter 312 are preferably formed from non-hardened circuitry when speed and/or circuit-fabrication are a concern.

With the desire to constantly scale down feature sizes of transistor and other components of integrated circuitry to increase the speed of the circuitry and pack more devices into the circuit-fabrication area, the capacitor 302 may be formed from a modified N-Channel or P-Channel MOS transistor along with the transistors of the first and second stages 104, 106. When compared to other fabrication techniques, forming the capacitor 302 in this way reduces processing steps and interconnects between the components of the circuit 300.

NMOS-formed Glitch Filter

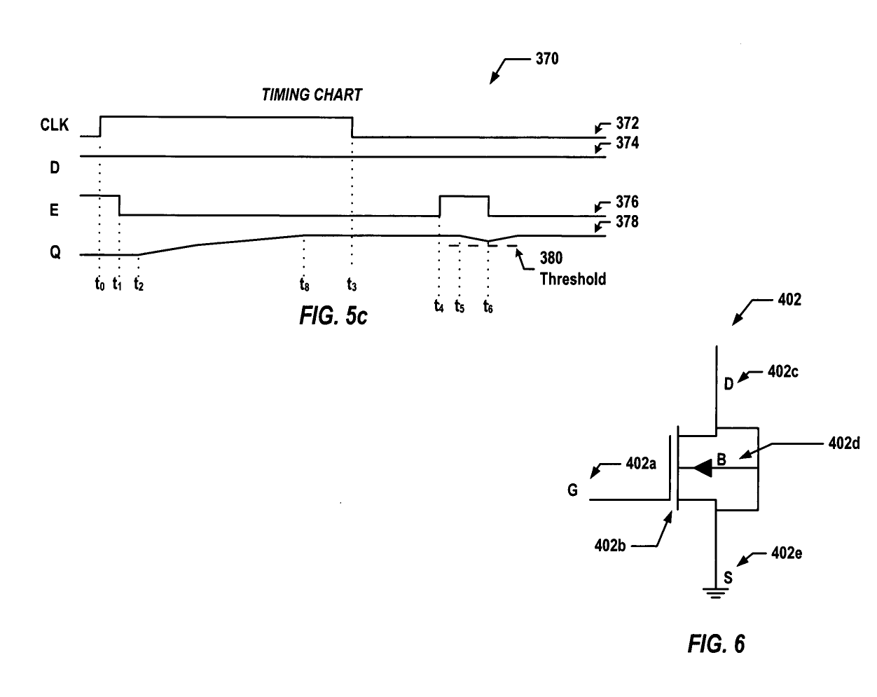

Referring now to FIG. 6, a modified NMOS transistor 402 embodiment of capacitor 302 is shown. One plate of the capacitor 302 may be formed from the gate 402a of the NMOS transistor 402. The dielectric of the capacitor 302 may be formed from the gate oxide 402b of the NMOS transistor 402. The second plate of the capacitor 302 may be formed from shorting together the drain 402c, body 402d and source 402e of the NMOS transistor 402.

By adjusting the area of the gate oxide 402b, the charge storing capacity of the capacitor 302 may be changed. For example, in one embodiment the gate oxide 402b of the NMOS transistor 402 is formed using an exemplary 0.35 um process and may have a thickness of about 8 nm. At this thickness, the capacitance is about 4.3 fF per square um. By making the gate area about 225-230 square um (or roughly about 15 um×15 um) the capacitance of the NMOS transistor 402 may be about 1 pF. As one skilled in the art will recognize, the gate area of the capacitor 302 may be enlarged to increase the capacitance, but eventually the NMOS transistor 402 may become too large for the overall circuit and/or undesirably slow down the response time of circuit 300.

As noted above, although additional fabrication steps and interconnects may be necessary, the capacitor 302 may be another type of capacitor, such as a metal-insulator-metal (MIM) capacitor. The MIM cap may be buried between interconnects of metallization layers (not shown) of the circuit 300. Details of an exemplary MIM capacitor may be found in co-pending U.S. patent application Ser. No. 10/754,946, filed on Jan. 8, 2004, and entitled “Semiconductor Device and Magneto-Resistive Sensor Integration,”; the entirety of which is incorporated herein by reference. The capacitor 302 may be formed from other components and techniques as well.

Referring back to FIG. 5a, a glitch-induced signal received on an input node 318 of the feedforward tri-state inverter 306 may be propagated past its input even when configured with redundant transistors. As will be described in more detail below, this can occur when a glitch-induced signal is impressed on an input terminal of the feedforward tri-state inverter 306 and the clocking signal is in a non-blocking mode. That is, the clocking signal allows signals present on the input node 318 of the feedforward tri-state inverter 306 to be passed to its output at node 320.

The effect of glitch-induced signal on a state of an output signal of the feedforward tri-state inverter 306 (“feedforward signal”) may then passed to the feedforward inverter 308. The feedforward inverter 308 inverts the feedforward signal and passes it to node 328. Without the glitch filter 102, the inverted version of the feedforward signal containing the glitch is passed immediately on to the second stage 106, resulting in a potential SEU condition.

However, the glitch filter 102 slows down the time rate of change of the inverted feedforward signal so as to create a slowed output signal. Being digital circuits, the second stage 106 and/or feedback tri-state inverter 312 will transition states if their signal only after slowed output signal satisfies a certain threshold, e.g., a HIGH or LOW state threshold.

Taking advantage of the charging and discharging time, the capacitor 302 effectively neutralizes the glitch when a duration of the glitch is less than the time it takes for the capacitor 302 to charge above a HIGH state threshold or discharge below a LOW state threshold. This can occur because the feedback signal that is passed from feedback tri-state inverter 312 to node 320 may place the feedforward signal back in its desired state before the slowed output signal reaches the HIGH or LOW state threshold of the second stage 106. Alternatively, the next clocked event of the input signal may place the feedforward signal in its desired state before the feedforward signal reaches the HIGH or LOW state threshold of the second stage 106.

Exemplary Glitch Filter Operation

FIG. 5b is timing chart 350 that illustrates exemplary signals present on various nodes of a latch circuit, such as the circuit 300 (FIG. 5a). As shown, the timing chart 350 includes Curves 352-358, and a HIGH-state threshold 360. Curve 352 illustrates a clocking signal (CLK) that may be fed to enable nodes 322, 334 of feedforward tri-state inverter 306 and feedback tri-state inverter 312, respectively. The complement to the CLK, namely CLKN, may be fed to complementary-enable nodes 332a, 334a of feedforward tri-state inverter 306 and feedback tri-state inverter 312, respectively.

Curve 354 illustrates the input signal that may be fed from input node 318 into the feedforward tri-state inverter 306. Curve 356 illustrates the nodal signal that is a resultant combination of the feedforward and feedback signals that may be fed to node 320 from the feedforward tri-state inverter 306 and feedback tri-state inverter 312, respectively. Curve 358 illustrates the slowed-output signal fed from the feedforward inverter 308 to node 328.

Referring now to Curves 352, 354 at time to, the CLK transitions to a HIGH state and the input signal received on input node 318 is in a HIGH state. Accordingly, the feedforward signal, which results from the inversion of the input signal, transitions from its previous state to a LOW state as shown at time t1. Sometime thereafter at time t2, the slowed output signal, which is fed to node 328, begins its transition to a HIGH state, as shown in Curve 358. By time t8, the slowed output signal satisfies a HIGH-state threshold 360, which is minimum level for being in a HIGH state. As such, the signal at node 328 is in the proper state given the HIGH state of the input signal.

At time t4, the input signal undesirably transitions from its HIGH state to a LOW state as a result of a glitch impressed on the input signal, as shown in Curve 354. In turn, the feedforward signal transitions from its desired LOW state to an undesired HIGH state, as shown in Curve 22 at time t5. Consequently, the slowed-output signal that is fed to node 328 begins, at time t6, to transition from its proper HIGH state to an improper LOW state.

At time t3 (Curve 352), the CLK transitions to a LOW state causing the feedforward signal at node 320 to be initially latched in the undesired HIGH state, as shown in Curve 356. But because of the glitch filter 102, the slowed-output signal on node 328 does not quickly transition to a LOW state, but rather, continues to satisfy the HIGH-state threshold 360 and keep the node 328 at the proper HIGH state.

Consequently, at time t7, the feedback signal, which is in a LOW state as a result of node 328 being at the proper HIGH state, is fed to node 320. The nodal signal on node 320 transitions to the desired LOW state, as shown in Curve 356. In turn, the slowed-output signal at node 328 reverses direction and begins to transition to its proper HIGH state. Thus, the glitch is not propagated to the node 328 or any other circuit downstream from such node.

FIG. 5c is timing chart 370 that illustrates exemplary signals present on various nodes of a latch circuit, such as the circuit 300 (FIG. 5a). In particular, the timing chart 370 includes Curves 372-378, and the HIGH-state threshold 360. Curve 372 illustrates a clocking signal (CLK) that may be fed to enable nodes 322, 334 of feedforward tri-state inverter 306 and feedback tri-state inverter 312, respectively. The complement to the CLK, namely CLKN, may be fed to complementary-enable nodes 332a, 334a of feedforward tri-state inverter 306 and feedback tri-state inverter 312, respectively.

Curve 372 illustrates the input signal that may be fed from input node 318 into the feedforward tri-state inverter 306. Curve 376 illustrates the nodal signal that is a resultant combination of the feedforward and feedback signals that may be fed to node 320 from the feedforward tri-state inverter 306 and feedback tri-state inverter 312, respectively. Curve 378 illustrates the slowed-output signal fed from the feedforward inverter 308 to node 328.

Referring now to Curves 372, 374 at time t0, the CLK transitions to a HIGH state and the input signal received on input node 318 is in a HIGH state. Accordingly, the feedforward signal, which results from the inversion of the input signal, transitions from its previous state to a LOW state as shown at time t1. Sometime thereafter at time t2, the slowed output signal, which is fed to node 328, begins its transition to a HIGH state as shown in Curve 378. By time t8, the slowed output signal satisfies the HIGH-state threshold 380. As such, the signal at node 328 is in the proper state given the HIGH state of the input signal. At time t3 (Curve 372), the CLK transitions to a LOW state, thereby latching node 328 in its proper high state.

At time t4, however, the feedfoward signal undesirably transitions from its LOW state to a HIGH state as a result of a glitch impressed upon it, as shown in Curve 376. In turn, the slowed-output signal that is fed to node 328 begins, at time t5, to transition from its proper HIGH state to an improper LOW state. But because of the glitch filter 102, the slowed-output signal on node 328 does not quickly transition to a LOW state, but rather, continues to satisfy the HIGH-state threshold 360 and keep the node 328 at the proper HIGH state.

Consequently, at time t6, the feedback signal, which is in a LOW state as a result of node 328 being at the proper HIGH state, is fed to node 320. The nodal signal on node 320 transitions to the desired LOW state, as shown in Curve 376. In turn, the slowed-output signal at node 328 begins to transition to its proper HIGH state. Like above, the glitch is not propagated to the node 328 or any other circuit downstream from such node.

Adjusting Glitch Filter Duration

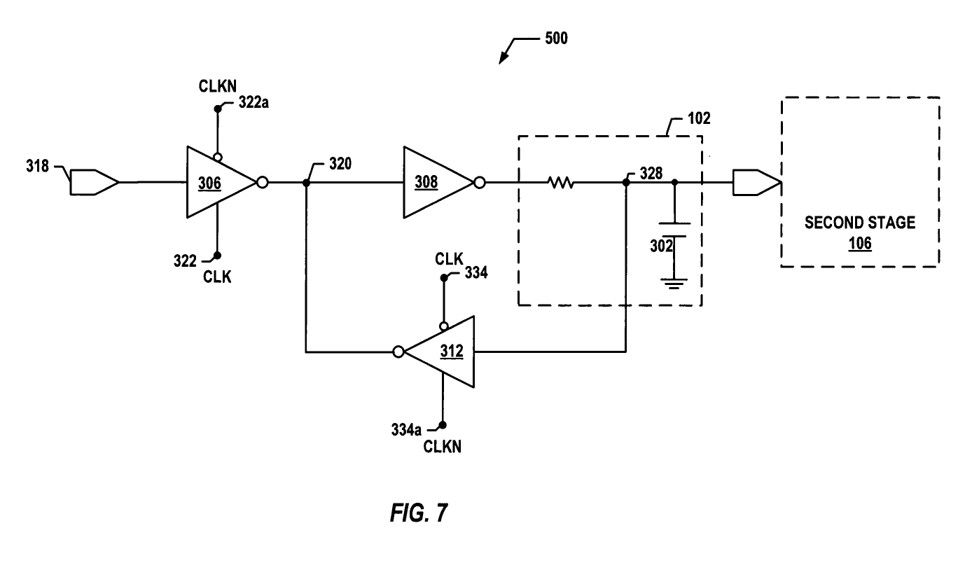

FIG. 7 is a block diagram illustrating a logic circuit 500 employing an alternative embodiment of the glitch filter 102. In this embodiment, the glitch filter 102 includes a resistor 504 in series with the capacitor 302 (or the intrinsic capacitance of the transistors of the second stage 106). The resistor 504 may be placed in series with feedforward inverter 308 and may be fabricated in several ways. Again, keeping with the desire to increase the speed of the circuitry and pack more devices into the circuit fabrication area, the resistor 504 may be, for example, fabricated as a body-implant, polysilicon and/or some other implanted resistor. Alternatively, the resistor 504 may be a thin film resistor.

The combination of the resistor 504 and capacitor 302 provide an RC filter having a time constant equal to the capacitance of the capacitor 302 times the value of the resistor 504 and any output resistance of the feedforward inverter 308. The value of the RC time constant may be varied by adjusting the values of resistor 504 and capacitor 302. Using the capacitor 302 described above, the value of the resistor 504 may be selected to neutralize a glitch having, for example, a typical duration of about 800 picoseconds. That is, if the capacitor 302 is at a value of about 0.01 pF, then the value of the resistor may be about 80 K ohms to filter such a glitch.

Conclusion

Exemplary embodiments of a device using having one or more semiconductor components and exemplary operation have been described. Because such an integrated device may be manufactured as a single chip, the user may realize advantages that include cost reduction, reduced size and increased functionality, among others.

In the foregoing detailed description, numerous specific details are set forth in order to provide a thorough understanding of exemplary embodiments described herein. However, it will be understood that these embodiments may be practiced without the specific details. In other instances, well-known methods, procedures, components and circuits have not been described in detail, so as not to obscure the following description.

Further, the embodiments disclosed are for exemplary purposes only and other embodiments may be employed in lieu of or in combination with the embodiments disclosed. For example, other (e.g., complementary) states of the signals discussed throughout this specification may be used in lieu of or in addition to those disclosed herein without affecting the operation of the disclosed embodiments or any of the numerous possible embodiments.

Moreover, it is contemplated that the above-described apparatus and components may be fabricated using Complementary-Metal-Oxide-Semiconductor(CMOS), bipolar, Gallium-Arsenide, Germanium, bipolarCMOS (BiCMOS), Indium Phosphide (InP), Silicon-On-Insulator (SOI), Microwave-On-Insulator (MOI), Silicon/Gallium Arsenide (Si/GaAs), Silicon/Germanium (SiGe), and/or Silicon/Carbide (SiC), Heterojunction Bipolar Transistor (HBT) fabrication processes, and/or Metal Semiconductor Field Effect Transistor (MESFET) fabrication technologies and processes.

The exemplary embodiments described herein may be deployed in various equipment and other devices, which may include or be utilized with any appropriate voltage source, providing any appropriate voltage, such as about 0.2-4, 5, 10, 12, 24 and 48 Volts DC, and about 24, and 120 Volts AC and the like.

Further, the claims should not be read as limited to the described order or elements unless stated to that effect. In addition, use of the term “means” in any claim is intended to invoke 35 U.S.C. §112, 6, and any claim without the word “means” is not so intended.

1. An apparatus for hardening a latch circuit against a single-event effect condition, the apparatus comprising:
a logic circuit having input and output nodes, wherein an input-signal event resulting from a radiation event is impressed upon the input node, and wherein the logic circuit propagates from its output node an output-signal event as a function at least a portion of the input signal event; and
a glitch filter coupled to the output node of the logic circuit, wherein the glitch filter filters from the latch circuit a portion of the output-signal event, and wherein when a duration of the output-signal event is less than a given period of time, the glitch filter filters from the latch circuit all of the output-signal event, thereby preventing further propagation of the input-signal event.

2. An apparatus for hardening a latch circuit against a single-event effect condition, the apparatus comprising:
a logic circuit having an input node for receiving an input signal and an output node for providing an output signal as a function of the input signal, wherein when a radiation-induced-signal event is impressed upon the input node causing the input signal to change state, the logic circuit propagates from its output node an output-signal event that is operable to cause the output signal to change state; and
a glitch filter coupled to the output node of the logic circuit, wherein the glitch filter filters from the latch circuit at least a portion of the output-signal event, and wherein when a duration of the output-signal event is less than a given period of time, the glitch filter filters from the latch circuit all of the output-signal event, thereby preventing the output signal from changing state.

3. An apparatus for hardening a latch circuit against a single-event effect condition, the apparatus comprising:
a first logic circuit for providing to a second logic circuit a plurality of output-signal events, wherein the first logic circuit provides to the second logic circuit a first output-signal event having a glitch impressed thereon, wherein when the first output-signal event satisfies a undesired-state threshold, then the second logic circuit operates in an undesired state; and
a glitch filter for slowing a rate of change of the first output-signal event by a given amount of time, wherein when a duration of the first output-signal event is less than the given amount of time, the glitch filter prevents the first output-signal event from attaining the undesired-state threshold, thereby preventing the second logic circuit from operating in the undesired state.

4. The apparatus of claim 3, wherein the first logic circuit comprises a clocked logic circuit, and wherein the clocked logic circuit provides to the second logic circuit the first output-signal at a first clocking event.

5. The apparatus of claim 3, wherein the first logic circuit provides to the second logic circuit a second output-signal event without a glitch impressed thereon, wherein when the second output-signal events satisfies a desired-state threshold, the second logic circuit operates in an desired state, wherein glitch filter slows a rate of change of the second output-signal event by the given amount of time, wherein when a duration of the second output-signal event is greater than the given amount of time, the glitch filter allows the second output-signal event to attain the desired-state threshold, thereby allowing the second logic circuit to operating in the desired state.

6. The apparatus of claim 5, wherein the first logic circuit comprises a clocked logic circuit, and wherein the clocked logic circuit provides to the second logic circuit the first output-signal at a first clocking event, and the second output-signal event at a second clocking event.

7. The apparatus of claim 3, wherein the glitch filter comprises a capacitor.

8. The apparatus of claim 7, wherein the capacitor is formed from a modified MOS transistor, wherein the gate of the MOS transistor provides a first plate of the capacitor, the gate oxide provides the dielectric of the capacitor, and the drain and source of the transistor are shorted together to provide a second plate of the capacitor.

9. The apparatus of claim 8, wherein the capacitor has a capacitance from about 0.01 pF to about 10 pF.

10. The apparatus of claim 8, wherein the gate oxide has a thickness from about 0.001 um to about 0.1 um.

11. The apparatus of claim 8, wherein the gate has an area from about 0.1 um² to about 100 um².

12. The apparatus of claim 3, wherein the glitch filter comprises a rate of change converting device consisting of a capacitor and resistor combination.

13. The apparatus of claim 3, wherein the glitch filter comprises a resistor coupled in series with the first logic circuit and the second logic circuit, whereby the resistor and inherent capacitance of the second logic circuit provide an RC time constant for slowing the rate of change of any of the plurality of output-signal events.

14. The apparatus of claim 3, wherein the glitch filter comprises (i) a resistor coupled in series with the first and the second logic circuits and (ii) a capacitor coupled in parallel with the first and second logic circuits, whereby the resistor, capacitor and inherent impedance of the second logic circuit provide an RC time constant for slowing the rate of change of any of the plurality of output-signal events.

15. The apparatus of claim 3, wherein the glitch filter slows the rate of change of the first output-signal event by a given amount of time to allow the first logic circuit to provide a second output-signal event without a glitch impressed thereon to prevent the first output-signal event from attaining the undesired-state threshold.

16. The apparatus of claim 15, wherein the first logic circuit comprises a clocked logic circuit, and wherein the clocked logic circuit provides to the second logic circuit the first output-signal at a first clocking event.

17. The apparatus of claim 15, wherein the first logic circuit provides to the second logic circuit a second output-signal event without a glitch impressed thereon, wherein when the second output-signal events satisfies a desired-state threshold, the second logic circuit operates in an desired state, wherein the glitch filter slows a rate of change of the second output-signal event by the given amount of time, wherein when a duration of the second output-signal event is greater than the given amount of time, the glitch filter allows the second output-signal event to attain the desired-state threshold, thereby allowing the second logic circuit to operating in the desired state.

18. The apparatus of claim 17, wherein the first logic circuit comprises a clocked logic circuit, and wherein the clocked logic circuit provides to the second logic circuit the first output-signal at a first clocking event, and the second output-signal event at a second clocking event.

19. The apparatus of claim 3, wherein the glitch filter is operable to (i) slow down a rate of change of the output-signal event by a given amount to produce a slowed-output-signal event, and (ii) provide to a second logic circuit the slowed-output signal event, wherein when the slowed-output-signal event satisfies a undesired-state threshold, then the second logic circuit operates in an undesired state, and wherein when a duration of the output-signal event is less than the given amount of time, the glitch filter prevents the slowed-output-signal event from attaining the undesired-state threshold, thereby preventing the second logic circuit from operating in the undesired state.

20. The apparatus of claim 3, wherein the glitch filter operable to (i) slow down a rate of change of the output-signal event by a given amount of time so as to produce a slowed-output-signal event, and (ii) provide to a second logic circuit the slowed-output-signal event, wherein when the slowed-output-signal event satisfies an undesired threshold, the second logic circuit operates in an undesired state; and
a feedback module operable to feed back to the glitch filter a feedback-signal event without a glitch thereon when the slowed-output-signal event does not satisfy the undesired-state threshold, wherein when a duration of the output-signal event is less than the given amount of time, the slowed-output-signal event does not satisfy an undesired-state threshold, thereby allowing the feedback module to neutralize the glitch impressed upon the output-signal event and prevent the second logic circuit from operating in the undesired state.

21. The apparatus of claim 3, wherein the first logic circuit comprises a first tri-state inverter, an inverter, and a feedback tri-state inverter.

22. In a latch circuit having a first logic circuit, a second logic circuit and a glitch filter, wherein the first logic circuit provides to a second logic circuit a plurality of output-signal events, and wherein the glitch filter slows down a rate of change of the output-signal events by a given amount of time, a method for hardening a circuit against a single-event effect condition comprising:
providing to the second logic circuit a first output-signal event having a glitch impressed thereon, wherein when the first output-signal event satisfies a undesired-state threshold, then the second logic circuit operates in an undesired state;
slowing a rate of change of the first output-signal event by a given amount of time, wherein when a duration of the first output-signal event is less than the given amount of time, the first output-signal event does not attain the undesired-state threshold, and
preventing the second logic circuit from operate in the undesired state.

23. The method of claim 22, further comprising:
providing to the second logic circuit a second output-signal event without a glitch impressed thereon, wherein when the second output-signal events satisfies a desired-state threshold, the second logic circuit operates in an desired state,
slowing a rate of change of the second output-signal event by the given amount of time, wherein when a duration of the second output-signal event is greater than the given amount of time, the second output-signal event attains the desired-state threshold, and
allowing the second logic circuit to operate in the desired state.
